(19) United States
(12) Patent Application Publication
(10) Pub. No.: US 2023/0142063 A1
(43) Pub. Date: May 11, 2023

(54) LIQUID/FLUID COOLING SYSTEMS FOR HIGH POWER-DENSITY (HPD) TRANSFORMERS

(71) Applicant: General Electric Company, Schenectady, NY (US)

(72) Inventors: Zhi ZHOU, Niskayuna, NY (US); Steve MANKEVICH, Cranberry Township, PA (US); Michael DOUCETTE, Aspinwall, PA (US); Anthony MARTIN, II, Valencia, PA (US)

(73) Assignee: General Electric Company, Schenectady, NY (US)

(21) Appl. No.: 17/916,342

(22) PCT Filed: Mar. 31, 2020
(86) PCT No.: PCT/US2020/026026

§ 371 Date: Sep. 30, 2022

(51) Int. Cl. H01F 27/12; H01F 27/24; H01F 27/30; H02M 5/458; H02M 1/00; H05K 7/20; H02M 7/00

(52) U.S. Cl. CPC H01F 27/12; H01F 27/24; H01F 27/306; H02M 5/458; H02M 1/0067; H05K 7/20927; H02M 7/003

(57) ABSTRACT

A high power-density power converter (500) employs a liquid cooling system (200) to cool its transformers (120). In an embodiment, the coils (135) of a transformer (100) are embedded in a heat-conducting solid (epoxy or resin). The resin-embedded coils (135) are in physical/thermal contact with cold plates (160), which are sandwiched between the coils (135) and/or in contact with exterior surfaces of the coils (135). The cold plates (160) may additionally or alternatively be in physical/thermal contact with the transformer core (145). Coolant fluid is pumped through the cold plates (160). In another embodiment, the transformer is (120) is immersed in a coolant fluid (740), such as oil, within a heat management enclosure (710). Cold plates (160) are in physical/thermal contact with the enclosure (710). Coolant liquid (240) pumped through the cold plates (160) conducts heat away from the oil-enclosed transformer (700).

### I. FIELD OF THE INVENTION

The present subject matter relates generally to cooling systems and to high-power electronics power systems, and more particularly to high power-density (HPD) transformers in high-power electrical power systems. The subject matter further relates to liquid cooling systems for HPD transformers.

### II. BACKGROUND OF THE INVENTION

Transformer Overview: A transformer is a passive electrical device that transfers electrical energy from one electrical circuit (the “source”) to one or more other electrical circuits (the “load(s)”), without any current transfer between the source and load(s). Energy is transferred via electrical field transmission only. A transformer has at least two separate wire coils, each typically wrapped around one or more ferrous (magnetic) metal cores. A varying current in any one source coil of the transformer produces a varying magnetic field (flux), which, in turn, induces a varying electromotive force across any other load coils wound around the same core. If the load coils are connected to electrical loads, current flows through the load coils. Electrical energy can be transferred between the (possibly many) coils, without a current-conducting metallic connection between the source and load circuits. This enables complete physical isolation of the source current and the load current(s).

Transformers are used in electric power applications for increasing alternating voltages at low current (Step Up Transformers) or decreasing the alternating voltages at high current (Step Down Transformer).

High Power Systems Overview: Medium-to-high power systems may provide electricity for large industrial plants, factories, large vehicles (such as large ships and airplanes), office buildings, apartment blocks, or entire cities. Power conversion systems, or power converters, transform electric power in medium and high power electronic distributed power buses and grids, for example: converting higher voltages to lower voltages; converting lower voltages to higher voltages; converting electricity from one alternating current frequency to another; or converting from direct current to alternating current, or alternating current to direct current.

Electrical power systems generally consists of generation, transmission, distribution and end use. Power is supplied by an electric generator or generators, or by renewable energy systems such as solar power. En route to its final load (devices which use the electric power), the power is typically received and transmitted on by one or more power converters. For example, a generator-side converter can receive alternating current (AC) power from the generator via a stator bus and can convert the AC power to a suitable output frequency, such as the grid frequency. The AC power is provided to the electrical grid via a line bus.

Low, medium, and high voltages are not rigidly defined, but for example the term “low voltage” may refer to voltages less than or equal to 1.5 kV, “medium voltage” may refer to voltages greater than 1.5 kV and less than 100 kV, and high voltage may refer to voltages at 100 kV and above.

High Power-Density (HPD) Power Systems—Power Converters for Ships and Other Environments With Compact Space Requirements: Certain environments, such as military and commercial ships, and also aircraft, place a premium on the utilization of space. As a result, ships require power converters which are more compact than those which may be employed in land-based environments. It is also desirable to reduce the weight of power conversion systems for maritime applications. Reductions in power converter volume and power converter weight lead to both improved power density and less drag on a ship.

The present system and method is particularly though not exclusively suited for microgrids such as those found on ships and airplanes. (Grids and microgrids are generally referred to in this document as “power systems.”) Power systems for ships and airplanes, as well as power systems suited for other compact physical spaces, benefit from being as physically small and compact as possible. For a given power level, the smaller the physical size the higher the resulting power density throughout the power system. High power densities in turn entail the generation of large amounts of undesired heat which needs to be dissipated.

One example of a high power-density (HPD) system is a Power Electronic Building Block (PEBB) Least Replaceable Unit (LRU), which is a structural and functional element of a power converter, and may be any power processor that converts any input electrical power to the desired voltage, current, and frequency output. PEBBs are intended for use as part of a modular and scalable power converter architecture typically employing multiple interconnected PEBBs.

A PEBB typically incorporates power devices, gate drives, transformers, and other components into a building block with a configurable and clearly defined functionality.

For reasons of energy-efficiency and effective ship-board space utilization, then, it is desirable to provide for PEBB LRUs with compact elements, high power densities, with the resulting high heat. Such PEBB LRUs, as well as other compact, high power systems, may entail the use of transformers which are both physically compact, and which step up lower voltages to higher voltages. Such high-power transformers may entail the use of 1:1 winding ratios, or may entail the use of K:N winding ratios, where N is a value equal or greater than K. The low volumes are particularly prone to heat dissipation, and the and high winding ratios result in still more heat generation and corresponding need for heat dissipation.

Heat Dissipation Overview: The power processing limits of power converters and power electronics building blocks (PEBBs) for power converters are largely determined by the thermal management of the high-frequency transformers employed in such systems. “Thermal management” is another way of referring to the heat dissipation abilities for the transformer, which in turns largely determines the volume and weight, and therefore the power density and specific power of the power converter.

Legacy power converters and power electronics building blocks (PEBB) have relied on air-cooled transformers. The heat generated from the transformer(s) during power converter operation is comprised of the Ft loss in the primary and secondary coils (coils loss), and the heat/power loss in the magnetic core (core loss).

The heat loss distribution among coils loss and core loss varies based on a specific design and materials used. Typical transformer cooling systems employ air cooling, which may for example include fans which force air around and through a transformer. This in turns requires ample space for air flow, as well as high air velocities, both of which may work against the goal of maintaining low overall volume for a power converter.

Given the aforementioned deficiencies, such as for example volumetric power density challenges, what is needed is a compact cooling system for medium-to-high voltage HPD electrical transformers. What is further needed is a cooling system which employs liquid cooling for efficient heat transfer. What is further needed is a cooling system which provides for structural integration with a power transformer, or which provides for a broad contact area between one or more liquid coolants and the electrically active, heat-generating elements of a power transformer.

### III. BRIEF SUMMARY OF THE INVENTION

This present system and method advances the air-cooled converter with a liquid-cooled thermal management solution to provide for improved volumetric power density, especially but not exclusively for space-constrained pulse load power converter applications, including for example and without limitation onboard a military or commercial ship, or onboard an airplane.

Liquid vs. Fluid: In general/common usage, the terms “liquid” and “fluid” are generally or loosely equivalent. In chemistry and physics, a “fluid” is anything that flows (including both liquids and gases), while a “liquid” is a nearly incompressible fluid that conforms to the shape of its container but retains a (nearly) constant volume independent of pressure. In this document the terms “liquid” and “fluid” both refer to flowing, nearly non-compressible materials with nearly constant volume. (So both terms broadly mean “a fluid which is a liquid but is not a gas”). However, in this document, “liquid” and “fluid” are further assigned distinct meanings:

(A) “Liquid” refers to a coolant liquid material 240 (see FIG. 2), which in some embodiments may be water, that is run through a cold plate 160 (see FIG. 1);

(B) “Fluid” refers to a heat-transfer liquid material 740 (see FIG. 7), which may in some embodiments be an oil, for use in direct contact with a transformer 120 inside a heat management enclosure 710.

The usage of “liquid” 240 (for example, water) vs. “fluid” 740 (for example, oil) is for convenience of reading only, to aid the reader in distinguishing the different types/applications for different liquids which provide cooling and/or which transfer and remove heat.

It will be noted that the consistent usage in this document of “coolant” in one context vs. “heat-transfer” in the other is also for convenience and for ease of reader comprehension. Other literature in the relevant arts may use such terms as “coolant” or “heat-transfer substance” equivalently, or with other significations.

### IV. BRIEF DESCRIPTION OF THE DRAWINGS

Advantageous designs of embodiment of the present invention result from independent and dependent claims, the description, and the drawings. In the following, preferred examples of embodiments of the invention are explained in detail with the aid of the attached drawings. The drawings, which are incorporated herein and form part of the specification, illustrate the present invention and, together with the description, further serve to explain the principles of the invention and to enable a person skilled in the relevant art(s) to make and use the invention.

FIG. 1 illustrates an exemplary transformer with integrated cold plates according to an embodiment of the present system and method.

FIG. 2 illustrates an exemplary liquid cooling system according to an embodiment of the present system and method.

FIG. 3A illustrates an exemplary transformer with integrated cold plates according to an embodiment of the present system and method.

FIG. 3B illustrates an exemplary transformer with integrated cold plates according to an embodiment of the present system and method.

FIG. 4 illustrates an exemplary transformer with integrated cold plates according to an embodiment of the present system and method.

FIG. 5 illustrates an exemplary power converter with multiple power electronic building blocks, each power electronic building block having an exemplary liquid cooling system.

FIG. 6A illustrates an exemplary transformer coil according to the present system and method.

FIG. 6B illustrates an exemplary transformer coil according to the present system and method.

FIG. 7 illustrates some elements of an exemplary fluid-immersed transformer according to an embodiment of the present system and method.

FIG. 8 illustrates some elements of exemplary fluid-immersed transformers according to embodiments of the present system and method.

FIG. 9 illustrates an exemplary application of a liquid or fluid cooled transformer integrated into a hybrid power electronics building block which may be used in a power converter.

Regarding text in the Figures: Any text in the figures is provided for convenience as an aid to understanding, to provide a reader with a verbal reminder as to the nature of some elements. Such text should not be construed a limiting, and different elements may be known or understood by additional or alternative labels, nomenclature, or alternative embodiments, as described within the written disclosure. For a more complete description of the elements illustrated, the reader is referred to the reference numbers shown in the drawings and to discussion in the disclosure associated with those reference numbers, as well as to other discussion in the disclosure where reference numbers may be omitted.

Specific functional or operational values shown in the figures (for example, voltage values, power values, structural dimensions, and other numerical values) should be construed as exemplary only and not as limiting, unless described as limiting in the written disclosure.

### V. DETAILED DESCRIPTION OF EMBODIMENTS OF THE INVENTION

While the present invention is described herein with illustrative embodiments for particular applications, it should be understood that the invention is not limited thereto.

The following detailed description is merely exemplary in nature and is not intended to limit the system, configurations, and methods taught, nor to limit the elements or steps of the system, configurations, and methods taught, nor to limit the applications of the present systems, methods, and configurations as disclosed herein. Further, there is no intention for the scope to be bound or limited to or by any theory presented in the preceding background or summary, nor in the following detailed description. Those skilled in the art with access to the teachings provided herein will recognize additional modifications, applications, and embodiments within the scope thereof and additional fields in which the invention would be of significant utility.

Throughout the application, description of various embodiments may use “comprising” language, indicating that the system and method may include certain elements or steps which are described; but that the system and method may also include other elements or steps which are not described, or which may be described in conjunction with other embodiments, or which may be shown in the figures only, or those which are well known in the art as necessary to the function of power systems. However, it will be understood by one of skilled in the art, that in some specific instances, an embodiment can alternatively be described using the language “consisting essentially of” or “consisting of.”

For purposes of better understanding the present teachings and in no way limiting the scope of the teachings, it will be clear to one of skilled in the art that the use of the singular includes the plural unless specifically stated otherwise. Therefore, the terms “a,” “an” and “at least one” are used interchangeably in this application.

Headings used in this detailed description are present only to assist in making this document readable and easy to navigate, and should not be construed as defining or limiting.

The system and method is not limited to the embodiments described below, which are exemplary only. Rather, the full scope of the system and method is recited in the claims which follow. It will be further understood that the appended claims are themselves disclosure, and the full scope of the system and method may include elements which are recited in the claims only.

### VI. EXEMPLARY LIQUID COOLING ELEMENTS AND SYSTEMS FOR TRANSFORMERS

Persons skilled in the art will appreciate that heat dissipation is necessary for effective operations of electric systems, including heat dissipation for transformers. Legacy power converters may employ air-cooling, for example cooling fans, or possibly only the general flow of air in the ambient environment, in some cases supplemented by vents and heat sinks.

As noted above, emerging power converters for compact environments may have a high power density (HPD) and a specific power which is significantly increased (as compared with the power density/specific power of a legacy power converters). The increased power density and specific power generates more volumetric or gravimetric heat (or heat per unit volume or weight) and higher temperature than is generated by legacy power converters. Further, such systems may employ the HPD transformers 120 for conversion of currents to high frequencies (HF), which further increases the generation of heat.

To dissipate the heat generated by HPD-HF transformers in HPD converters, a liquid-based cooling system may be employed for the HPD transformers 120, either in combination with air-based cooling or to substantially replace air based cooling for the transformers 120.

In particular, the combination of higher voltages, multiple transformer windings, and the more compressed size of the HPD power converter as a whole may result in intense heat generation by the HPD-HF transformers 120. The heat generated from the HPD-HF transformers 120 during operation is comprised of the Ft loss (current-squared (I²) time loss) in the primary and secondary coils (coils loss), and the heat/power loss in the magnetic core (core loss) of the transformers 120.

In some embodiments, the present system and method introduces dedicated liquid based cooling for HPD-HF transformers 120.

Thus, in some embodiments, the present system advances air-cooling with a liquid-cooled thermal management solution to further improve volumetric power density for especially space constrained pulse load converter applications (for example, onboard a military or commercial ship). The heat loss distribution among coils-loss and core-loss varies based on a specific design and materials used. To reduce volume and increase power density, embodiments of the present system and method employ a liquid-cooled HPD-HF transformer 100, with a liquid-cooled solution for the thermal management of the transformer coil components 135.2, 135.1 and transformer core 145.

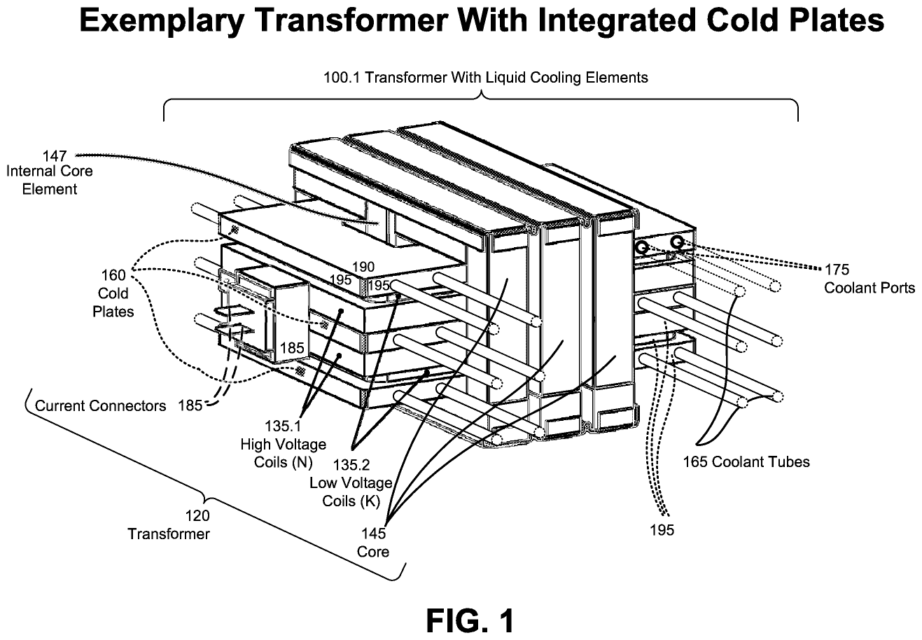

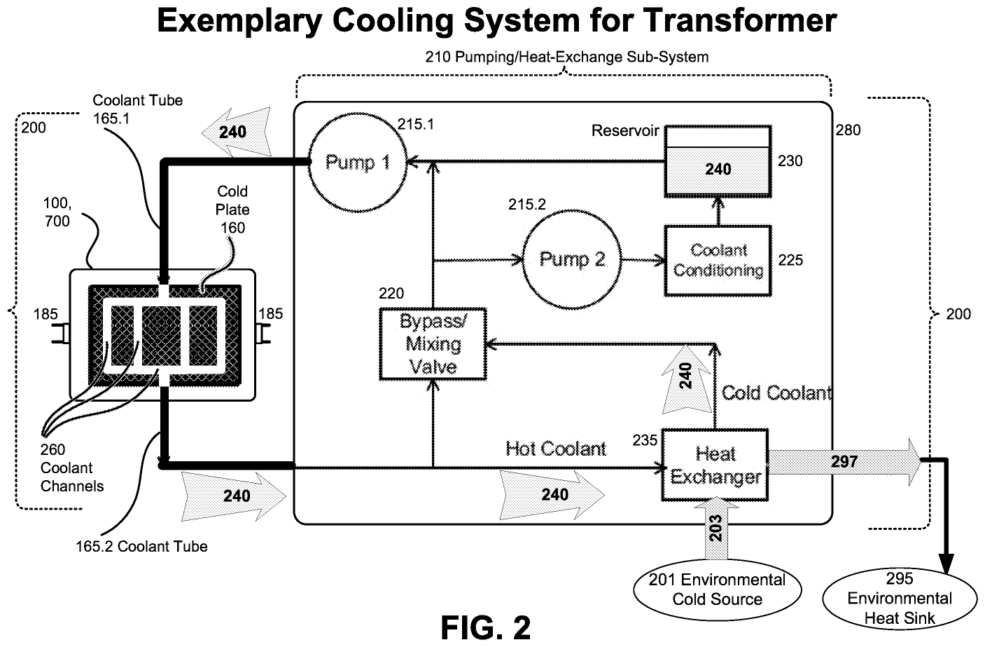

Exemplary HPD-HF Transformer with Integrated cold plates: FIG. 1 provides a schematic illustration of an exemplary HPD-HF transformer 120 with integrated cold plates 160 of a liquid cooling system 200 (see FIG. 2) (in FIG. 1, the combined transformer 120 proper (that is, the coils plus magnetic core) with integrated cold plates 160, hereinafter “TICP”, is labeled with reference number 100.1), according to one embodiment of the present system and method. In an embodiment, TICP forms structurally integrated units, that is, with some elements 160, 165 of the liquid cooling system 200 embedded within the structure of HPD-HF transformer 120.

Coil Components (Coils) and Cores: In an embodiment, the HPD-HF transformer 120 includes one, two, or more primary (high voltage/HV) coil components 135.1; one, two, or more secondary (low voltage/LV) coil components 135.2; one, two, three or more magnetic (ferrous) cores 145 (three shown in the figure), and electrical connections 185 (only one shown in the figure). One or more of the cores 145 may have one or more internal core element(s) 147 which may run through a gap or gaps in the coils 135 and/or gaps in the cold plates 160. The internal core element(s) 147 may only provide structural support, or be made of ferrous materials to provide for additional magnetic coupling/inductance between the coils 135.

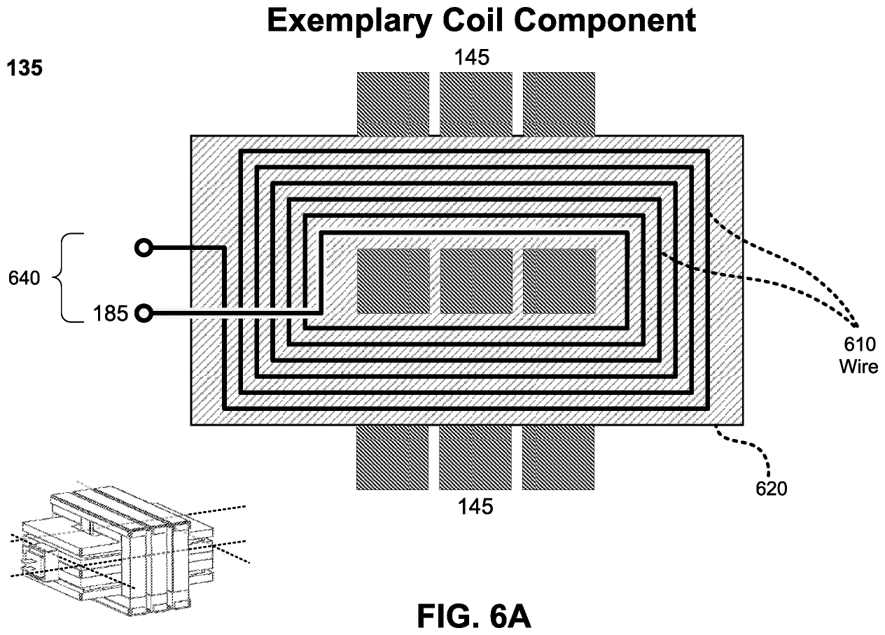

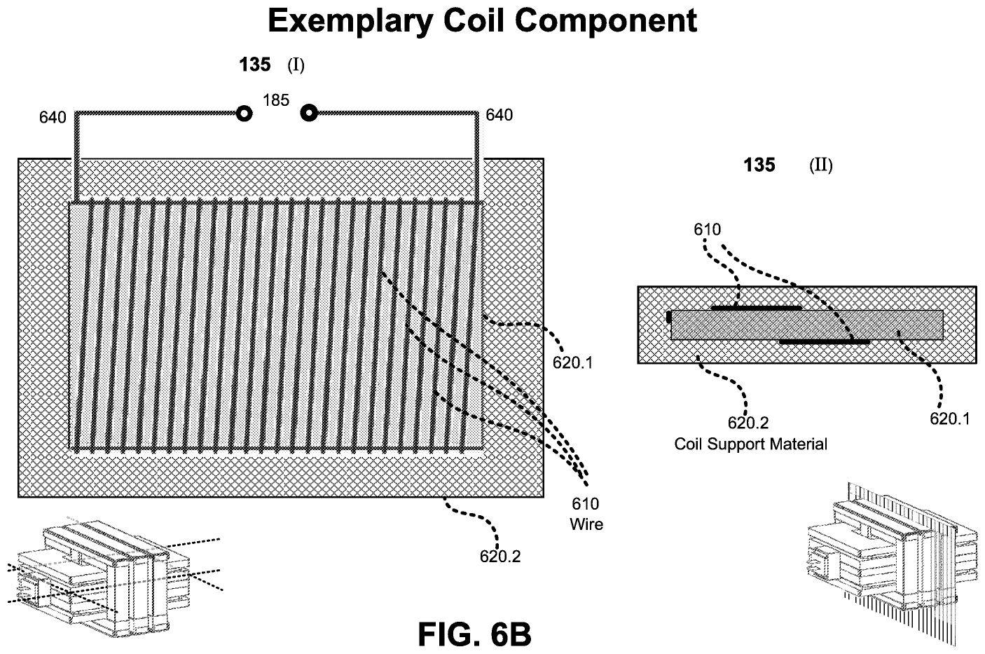

The metallic, electrically conducing elements 610 of the primary coils 135.1 and secondary coils 135.2 are not actually illustrated in FIG. 1 (see instead FIGS. 6A and 6B); rather, illustrated in the figure are the exteriors of the solid coil components 135.1, 135.2, which may for example be made of silicon, resins, epoxies, ceramics, glass, or other non-electrically-conducting substance or materials 620.1, 620.2 (see FIGS. 6A and 6B for cross-sectional view of the coils 135), with the electrically conducting (typically metallic) coils 610 embedded within. In this document, for brevity, the “coil components” 135 are typically referred to in brief simply as “coils” 135. In one exemplary embodiment, the coil wires 610 may be Litz wire.

The epoxy, resin, glass, ceramic material or similar bonding/enclosure material is referred to generally as the “coil support material” 620.1, 620.2, and is an effective heat conductor. Heat generated by the electrically conducting elements (such as wires, filaments, or foils) 610 of the coils 135 is readily transferred into the surrounding epoxy, resin, or ceramic material 620.1, 620.2 of the coils components 135.1, 135.2.

In the exemplary embodiment shown, three cold plates 160 (also referred to as “heat exchange plates” 160) are physically inserted or sandwiched between, and in substantial contact with, all of the coil components 135.1, 135.2 and the core(s) 145. In an embodiment, the cold plates are made of a non-ferrous (non-magnetic) metal. In an alternative embodiment, the cold plates 160 may be made of other non-ferrous, non-metallic materials which are suitable for conducting heat.

Running through each cold plate 160 are one or more internal liquid transport channels 260 (or “coolant channels” 260) (not illustrated in FIG. 1, see FIG. 2) suitable for conducting a coolant liquid 240 (see FIG. 2) such as deionized water, chilled water, or processed water with or without petro-chemical additives, or other coolant liquids 240.

Two or more coolant tubes 165 (or “coolant pipes” 165) are connected to the cold plates 160 at coolant ports 175, which are fluid input/output ports along an exterior surface of the cold plates 160. The coolant ports 175 may have valves or other fluid control mechanisms not shown in the figure. The coolant tubes 165 transfer the liquid coolant 240 into and out of the interior coolant channels 260 of the cold plates 160. Transport of the coolant liquid 240 through the interior coolant channel(s) 260 of the cold plates 160 conducts heat away from transformer 120, and serves to maintain the transformer 120 at a safe operating temperature during power conversion.

In an alternative embodiment, exterior coolant tubes 165 or coolant pipes 165 may be integrated into cold plates 160, bonded or otherwise attached to coolant ports 175, and/or be integrated extensions of interior coolant channels 260.

Persons skilled in the art will appreciate that thin layers of various additional heat conducting materials (not shown in FIG. 1), such as thermal binding materials or glues, may be used to help bond or adhere the surfaces of the coils 135.2, 135.1 and the core 145 with the surfaces of the cold plates 160. Such thermal heat conducting materials may also help to maintain efficient and uniform heat transfer. In some embodiments, such thermal heating conducting materials may be applied in thin layers, on the order of 1 mm or less; in alternative embodiments, thicker layers may be used; in alternative embodiments, no additional heat conducting materials or glues are used for bonding. Instead, the coils 135.2, 135.1 and cold plates 160 may be bound together and maintained in thermal contact via mechanical means such as screws (not shown in the figure), clamps (not shown), bolts (now shown), or via the containment and pressure exerted by the surrounding cores 145.

In an alternative embodiment, some or all of the coils 135.2, 135.1 and cold plates 160 may be bound together and maintained in permanent thermal contact during manufacturing process by: (i) using heat, compression, application of surface solvents, or similar means to melt, partially melt, or chemically soften a thin surface layer and/or the edges of the coils 135.2, 135.1 and/or cold plates; (ii) mechanically pressing together the coils 135.2, 135.1 and/or cold plates; and (iii) then allowing the surfaces/edges so treated to physically harden and bond together at a molecular level.

In alternative embodiments, combinations of two or more of screws, clamps, bolts, the cores 145, thermal heat conducting materials and glues, and chemical/heat bonding may be used to maintain contact, pressure, and the necessary degree of thermal conductivity between the coils 135.2, 135.1 and the cold plates 160.

In further discussion in this document, a “cold plate” is sometimes abbreviated by a capital “C”, the secondary/low-voltage coils by “S”, and the primary/high-voltage coils by “P”. Various embodiments of the present system and method may be referred to, in brief, according to the stacking order of these elements. For example, in the exemplary embodiment 100.1 of FIG. 1, the stacking order is “C-S-P-C-P-S-C”.

Major (Larger) Surfaces: It will be apparent from the figures that in some embodiments, and in some geometries, some flat surfaces 190 or substantially flat surfaces 190 of the cold plates 160, the coils 135, and/or the core(s) 145 may be the largest surfaces of those elements, or may be one of two opposing largest surfaces. Such largest surfaces 190 are referred to in this document as “major surfaces” 190, and it will be apparent that such major surfaces 190 are particularly well-suited for heat transfer to the cold plates 160. Smaller, minor surfaces 195 may facilitate heat transfer as well. In alternative embodiments, some transformer components 135, 145 may be approximately or substantially cubical, in which case the area distinction between major surfaces 190 and minor surfaces 195 may be insignificant.

Exemplary Liquid Cooling System (LCS)

Persons skilled in the relevant arts will appreciate that a full or functionally complete liquid cooling system 200 for transformer 120 will include not only the liquid cooling elements (LCS) 160, 165 and coolant liquids (s) 240 of cooling system 100.1, but also various additional elements, some or all of which may be external and possibly remote from transformer 120.

FIG. 2 illustrates an exemplary liquid cooling system (LCS) 200 for a HPD-HF transformer 120 according to the present system and method. Exemplary LCS 200 and other LCS systems consistent with the scope of the appended claims may employ, among other elements:

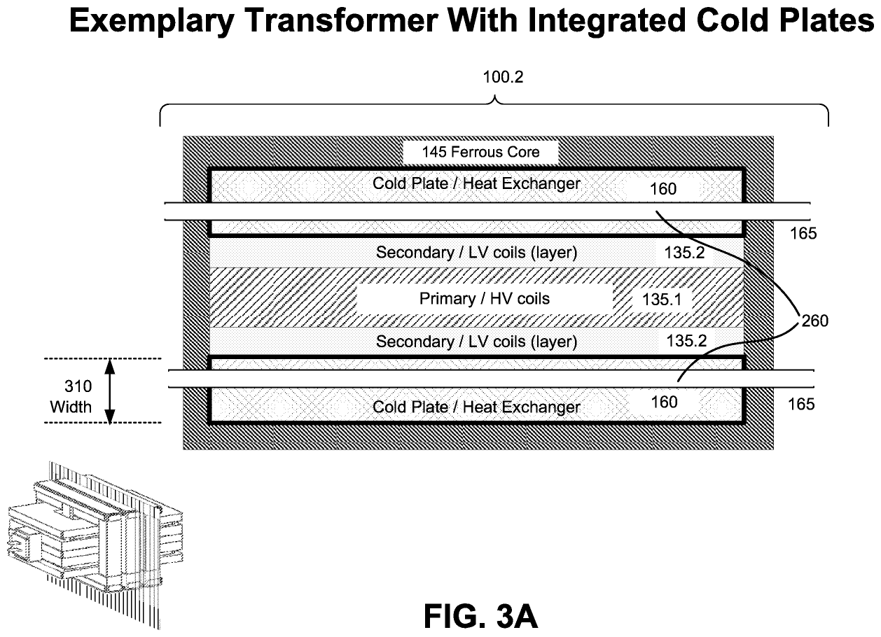

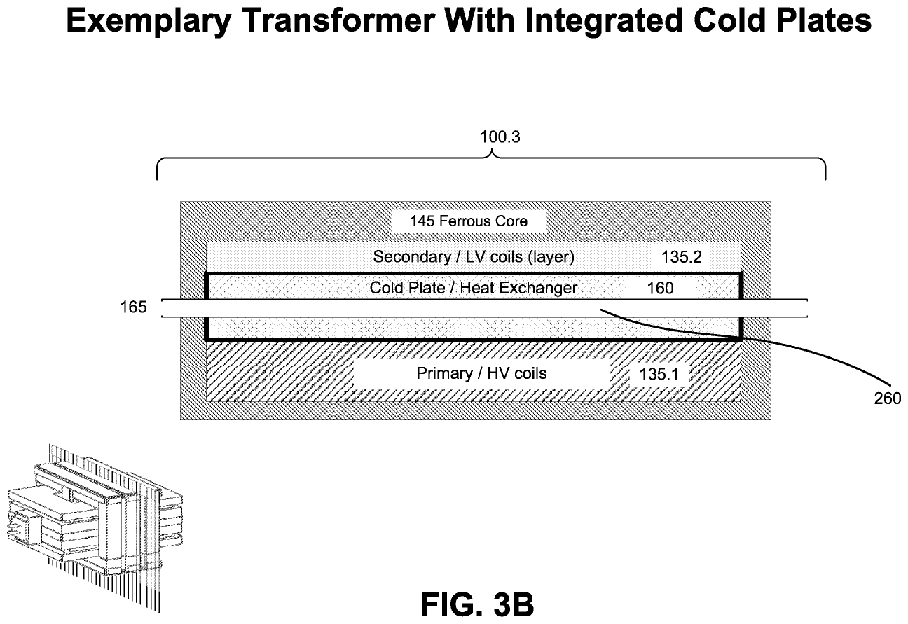

(i) the exemplary transformer with integrated cold plates (TICP) 100 discussed above in conjunction with FIG. 1 (and see also FIGS. 3, 4, 5, and FIG. 6);

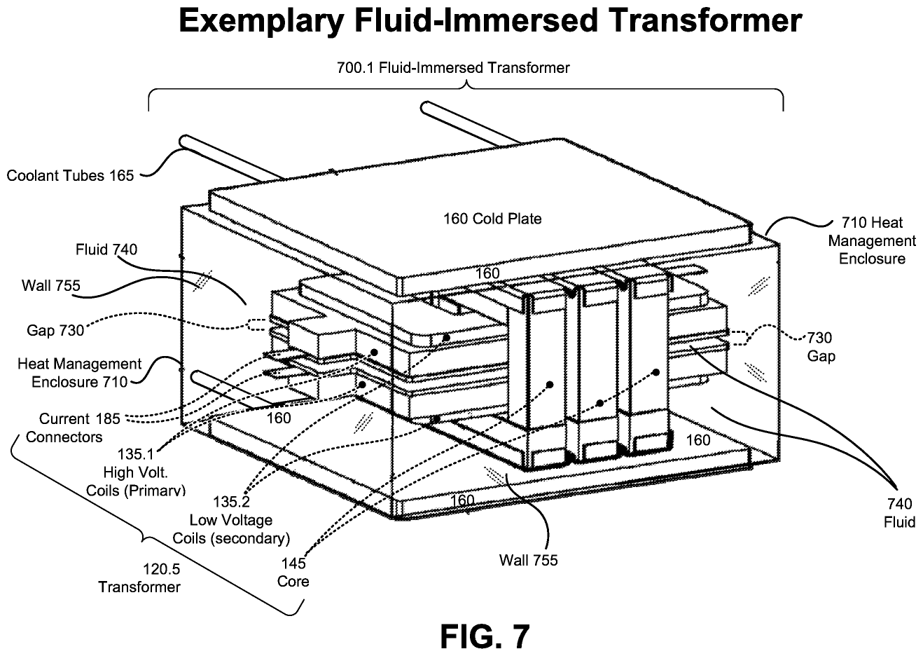

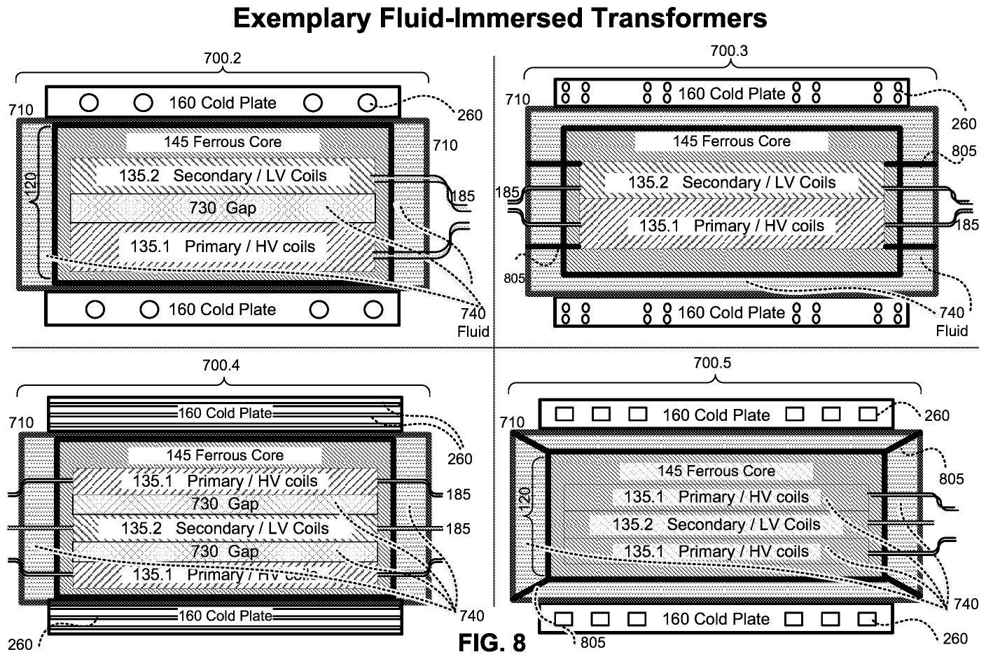

(ii) the exemplary fluid immersed transformers (FIT) 700 (see FIGS. 7, 8, and also FIG. 6, for further discussion);

(iii) any transformers consistent with the scope of the appended claims.

The LCS 200 includes one or more cold plates 160, already discussed above, which are bonded to, embedded within, or otherwise in close structural contact with/thermally coupled with elements of the HPD-HF transformer 120.

Cold plates: It will be noted that while, in the figures in this document, the cold plates 160 are illustrated as substantially cuboid with six substantially flat, mutually orthogonal surfaces, other shapes are possible. In some embodiments of the present system and method, it may prove advantageous for the cold plates to be molded to non-cuboid shapes, or into modified cuboid shapes with various extensions, to better conform to, increase surface contact, or increase current or magnetic interactions with other elements 135.2, 135.1, 145 of the transformer 100. In some embodiments of the present system and method—and possibly to reduce the weight of the cold plates 160, provide for additional thermal conductivity, or to provide supplemental air-cooling for the cold plates 160—it may prove advantageous for the cold plates to have textured surfaces, including for example and without limitation: ridges, bumps, grooves, other textures or variations in the surface height, or to have non-linear (curved) portions.

In some embodiments, the cold plates 160 may be made of a single metal, a single metal alloy, a single ceramic material, a single polymer material, carbon-based material, or other single non-ferrous, non-electrically conducting, but heat-conducting material. In alternative embodiments, the cold plates 160 may be made from two or more materials, for example separate, different materials may be used for a first side of the cold plate, a second side of the cold plate, and possibly a third material for the lining of the interior channels 260 (discussed below). In an embodiment, surfaces of the cold plates which are exposed to the air may have an insulating material attached to the exposed surfaces to prevent heat leakage, to prevent fires or burns, and/or to maintain maximum heat transfer through the coolant channels 260.

Coolant channels: Interior to the cold plates 160 are one or more coolant channels 260 which conduct coolant liquid 240 through the cold plates 160. It will be noted that the number, geometric configuration, relative width and/or diameter (in relation to the size of the cold plate), and arrangement of the coolant channels 260 illustrated in FIG. 2 is exemplary only; many alternative arrangements of coolant channels 260 may be employed within the scope of the present system and method. The coolant channels 260 can be bulk/macro channels (with diameters on the order of the shortest-width 310 (see FIG. 3A) of the cold plates 160, or may be micro-channels with diameters substantially smaller than the shorter width 310 of the cold plates 160.

It will be further noted that while the coolant channels 260 are described in this document as “interior” to the cold plates 160, “interior channels” are construed to include cooling channels for which the metallic surface of the cold plates 160 may extend or protrude partially above a flat, smooth, or ridged surface of the cold plates 160; and/or cooling pipes (for example, metal pipes) carrying the coolant liquid 240 which are bonded to the flat, smooth, or ridged surfaces of the cold plates 160.

Coolant tubes: Feeding liquid coolant 240 into and out of the coolant channels 260 within the cold plates 160 are one or more inflow coolant tubes 165.1 and one or more outflow coolant tubes 165.2. Here again, the single inflow coolant tube 165.1 and single outflow coolant tube 165.2 illustrated in FIG. 2 are exemplary only, and (as in FIG. 1) greater numbers of coolant tubes 165 may be employed. While both FIGS. 1 and 2 illustrate coolant tubes 165 as entering/exiting the cold plate 160 along a narrow side surface 185, this is exemplary only. In alternative embodiments, one or more coolant tubes 165 may be attached, and provide for coolant inflow or outflow, along a larger planar surface 190 of a cold plate 160.

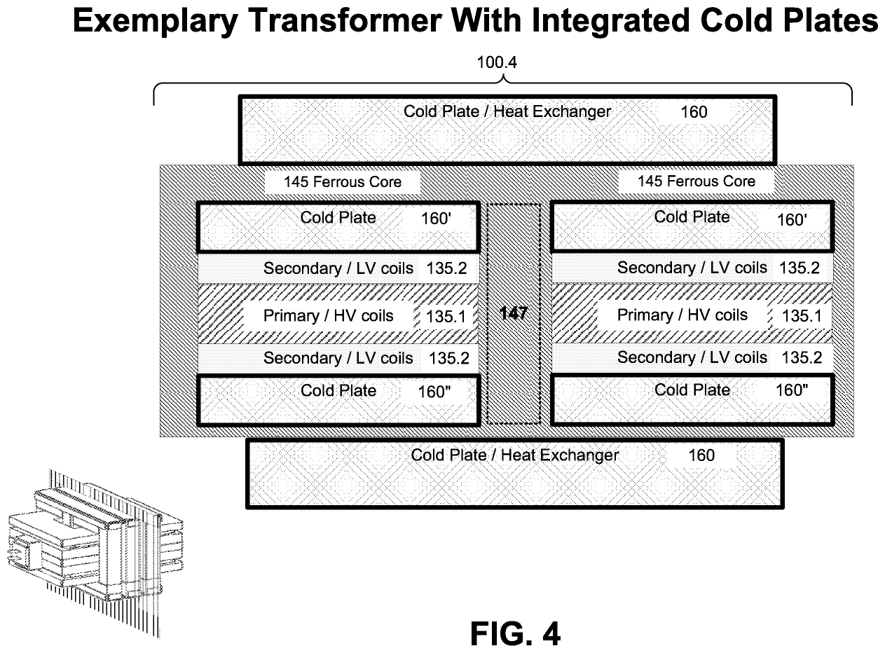

Exemplary cooling system 200 may also include, for example and without limitation: more or fewer cooling plates 160; one or more alternative or additional cold plates 160 bonded to exterior surface(s) of the magnetic cores 145 (see FIG. 4); other alternative geometries; and other variations within the scope of the appended claims.

Exemplary cooling system 200 may also include a pumping/heat-exchange sub-system 210, referred to in the appended claims simply as “pumping system (210)”, and which may also be referred to as a “regulatory system” 210, “filtering system 210”, “coolant conditioning system” 210, and other similar terms. Pumping/heat-exchange sub-system 210 may include for example and without limitation:

(i) Liquid pumps 215. In an embodiment, a first coolant pump 215 provides pressure to drive cold coolant 240 into the cold plate 160 via input coolant tube(s) 165.1; while a second coolant pump 215 pressures either or both of a used coolant and a fresh coolant (from bypass/mixing valve 220) into a coolant conditioning unit 225. The two pumps shown are exemplary only. Other pumps may be employed as well, for example a fresh coolant input pump (not shown in the figure) to draw fresh cold coolant liquid 240 either directly into coolant tubes 165 or into a heat exchanger 235;

(ii) a heat exchanger 235 to remove heat from hot coolant 240 for transfer to an environmental heat sink 295; and/or to provide cooling for liquid coolant 240 via an environmental cold source 201;

(iii) a bypass/mixing valve 220 which may recycle some of heated coolant 240 by mixing it with fresh coolant liquid 240, or by alternately using cold coolant 240 and recycled hot liquid 240;

(iv) a coolant conditioning unit 225 which may clean or filter coolant liquid 240 to remove metal or non-metal particles, dirt and extraneous chemicals, or which may provide chemical additives (such as antifreezes) to the coolant liquid 240;

(v) a coolant reservoir 230 which provides a short-term reserve or coolant buffer for coolant liquid 240.

Persons skilled in the relevant arts will recognize that exemplary cooling system 200, and in particular pumping/heat-exchange system 210, may include other elements not shown in FIG. 2, including for example and without limitation: valves; temperature sensing devices; pressure sensing devices; additional chemical or coolant reservoirs; internal processing and memory to control the cooling system 220 via software and firmware; internal electrical systems to power the pumps 215, valves, processor, and memory; and input and output control/data ports for external monitoring of the cooling system 200. Such additional elements will, in some embodiments, be structurally part of a PEBB LRU and/or a power converter which contains one or more transformers with liquid cooling elements 100, 700.

In an embodiment of the present system and method, multiple elements of pumping/heat-exchange subsystem 210 may be commonly housed and structurally combined in a sub-system enclosure 280, providing for convenient mounting and modularity. In an embodiment of the present system and method, the pumping system 210 elements within the enclosure 280 may provide pressure, conditioned coolant, and heated coolant removal for multiple transformers 100 (the one, single transformer 100 shown in FIG. 2 being exemplary only, and not limiting.)

No Air-Based Cooling or Limited Air-Based Cooling: It will be apparent from the above description and figures, as well as further description and figures below, that the liquid-based transformer cooling of the present system and method removes all or substantially most of the heat generated by the transformer 120 via heat transfer through the solid material components of the transformer, the cold plates 160, and the liquid coolant 240. In some embodiments, heat transfer via the ambient air immediately surrounding transformer 120 may be essentially negligible.

In alternative embodiments, heat transfer from the transformer 120 via the proximately surrounding air may provide some amount of substantive or beneficial additional cooling; but the dominant mode for heat removal is still primarily via: (i) the flow of heat from the transformer coils 135 and core(s) 145 into the cold plates 160, and then (ii) from the cold plates 160 to an external environmental heat sink 295 via the liquid coolant 240 running through the cold plate(s) 160.

Cold Source and Environmental Heat Sink: The exemplary environmental cold source 201 and the exemplary environmental heat sink 295 illustrated in FIG. 2 are understood to be elements of the larger environment apart from the exemplary cooling system 200. For example, for a ship-based power converter application, both the environmental cold source 201 and the environmental heat sink 295 may be an overall shipboard process water or chill water supply system, water in the sea, ocean, or river in which a ship travels. For another example, for an airplane-based power converter application, both the environmental cold source 201 and the environmental heat sink 295 may be the air external to the aircraft.

FIG. 3A illustrates an exemplary HPD-HF transformer 120 with integrated cold plates (TICP) of a liquid cooling system 200 (see FIG. 2). (In FIG. 3A, the combined transformer 120 with integrated cold plates (TICP) is labeled with reference number 100.2). Some elements of exemplary TICP 100.2 are the same or substantially similar to elements of the exemplary TICP 100.1 of FIG. 1 and/or cooling system 200 of FIG. 2; to avoid redundancy, some details of those elements already described in FIG. 1 and/or FIG. 2 are not repeated here.

In FIG. 3A, the transformer with integrated cooling plates (TIPC) 100.2 is shown in cross-sectional view, and with some elements omitted as compared to the embodiment 100.1 of FIG. 1. In the cross-sectional view of FIG. 3A an internal core element 147 is not present.

In TICP 100.2, only a single primary coil 135.1 is employed, which is sandwiched between two secondary coils 135.2. Two cold plates 160 are employed on the outer surfaces of secondary coils 135.2. The cold plates 160 are in thermal contact with the magnetic core 145 as well. Coolant pipes 160 with interior channels 260 running through the cold plates 160 (or heat exchange plates 160) are shown as well. In TLCS 100.2, the stacking order is “C-S-P-S-C”.

FIG. 3B illustrates another exemplary HPD-HF transformer 120 with integrated cold plates (TICP) 100.3 of a liquid cooling system 200. (In FIG. 3B, the combined transformer 120 proper with integrated cold plates (160) (TICP) is labeled with reference number 100.3).

In FIG. 3B, the transformer with integrated cooling plates (TIPC) 100.3 is shown in cross-sectional view, and with some elements omitted as compared to the embodiment 100.1 of FIG. 1. In the cross-sectional view of FIG. 3B an internal core element 147 is not present.

Some elements of exemplary TICP 100.3 are the same or substantially similar to elements of the exemplary TICP 100.1 of FIG. 1 and/or cooling system 200 of FIG. 2, and details of those elements already described in FIG. 1 and/or FIG. 2 are not repeated here.

In FIG. 3B, the TICP 100.3 is shown in cross-sectional view, and with some elements omitted as compared to the embodiment 100.1 of FIG. 1. In TICP 100.3, only a single primary coil 135.1 and a single secondary coil 135.2 are employed, with a single cold plate/heat exchange plate thermally coupled between them. The cold plate 160 is in limited thermal contact with the magnetic core 145 as well. In TICP 100.3, the stacking order is “S-C-P”.

FIG. 4 illustrates another exemplary HPD-HF transformer 120 with integrated cold plates (TICP) 100.4 of a liquid cooling system 200. Some elements of exemplary TICP 100.4 are the same or substantially similar to elements of the exemplary TICP 100.1 of FIG. 1 and/or cooling system 200 of FIG. 2, and details of those elements already described in FIG. 1 and/or FIG. 2 are not repeated here. In the cross-sectional view of FIG. 4 an internal core element 147 is present (so that two single cold plates 160′ and 160″, as well as each single coil 135, appears to be split into two parts).

In FIG. 4, the TICP 100.4 is shown in and with some elements omitted as compared to the embodiment 100.1 of FIG. 1. In TICP 100.4, only a single primary coil 135.1 and two secondary coils 135.2 are employed. Four cold plates/heat exchangers 160 are employed: (i) Two cold plates 160′, 160″ are physically and thermally coupled with two respective surfaces of the two secondary coils 135.2, and are in interior physical/thermal contact with the magnetic core 145 as well; and (ii) Two cold plates 160 are attached to and thermally coupled with exterior surfaces of the ferrous core 145. In TICP 100.4, the stacking order is “C-F-C-S-P-S-C-F-C”.

The arrangements and ordering of elements of primary coils 135.1, secondary coils 135.2, cold plates 160, and ferrous core parts 145, 147 illustrated and discussed in embodiments above are exemplary only and not limiting. Other arrangements may readily be envisioned within the scope of the appended claims, as discussed further below.

Generalized Transformer Component Arrangements: As will apparent to persons skilled in the relevant arts, and based on the above discussion and associated figures, various embodiments of the liquid cooled transformer (100) may include, for example and without limitation, and alone or in some cases in combination:

(i) A first major surface 190 (a largest surface or one of two largest surfaces) of the cold plate 160 being in contact with and thermally coupled with a second major surface 190 of the at least one of (i) the core 145 and (ii) one of the coil components 135.1, 135.2. The first and second major surfaces 190 are so mutually shaped as to facilitate extended surface contact and thereby the effective transfer of heat between the first major surface 190 and the second major surface 190. (See for example FIGS. 1, 3A/B, 4, and 5.) (Note that in FIG. 1, the contact major surfaces of the core 145 and the coil components 135 are not labelled with a references number, as these contact surfaces are obscured from direct view.)

(ii) The liquid cooled transformer (160) as described in list item (i) immediately above, where the first major surface 190 and the second major surface 190 are flat surfaces. (See for example FIGS. 1, 3A/B, 4, and 5.)

(iii) A single cold plate 160 has a first major surface 190 and a second opposing major surface 190, each of the two opposing major surfaces 190 in contact with a major surface 190 from a different one of the transformer elements from among the core (145) and the two coil components (135.1, 135.2). (See for example FIGS. 1, 3A/B, 4, and 5.)

(iv) A single cold plate 160 is physically situated between, in physical contact along its major surfaces 190 with, and thermally coupled along those major surfaces 190, with at least one of: (a) both the core 145 and one of the coil components 135.1, 135.2 (see FIGS. 1, 3), or else (b) with two coil components 135.1 (see FIGS. 1, 4, 5).

(v) At least two separate cold plates (160), where the at least two cold plates (160) are configured and arranged to be in physical contact with and in thermal contact with at least two different, non-adjoining transformer elements from among the core (145), the first coil component 135.1, and the second coil component 135.2. (See FIG.

(vi) At least two separate cold plates (160), where the at least two cold plates (160) are configured and arranged to be in physical contact with and in thermal contact with at least three different transformer elements from among the core (145), the first coil component (135.1), and the second coil component (135.2). (See FIGS. 1, 3, 5.).

(vii) Two or more primary coils 135.1, and/or two or more secondary coils 135.2 (see FIGS. 1, 3 and 5) may be employed. Such embodiments will typically but not necessarily employ two or more separate cold plates 160, which are sandwiched between various coils 135.

(viii) A primary coil 135.1 and a secondary coil 135.2 may be placed in direct physical and thermal contact, with one or two cold plates 160 attached to the directly-physically coupled coils 135 for heat removal from both.

(ix) A single cold plate 160 may be configured for direct physical and thermal contact with two different coils 135 (135.1/135.1, 135.1/135.2, or 135.2/135.2) and also with direct physical and thermal contact from one or more cores 145, for heat removal from both the coils 135 and the cores. In some embodiments, this is accomplished by having at least one of the minor sides 195 of the cold plate 160 in contact with the core(s) 145, while the facing major sides 190 of the cold plate 160 are in contact with the two different coils 135.

In general, other geometric arrangements, as well as the shapes and relative sizes of the coils 135, core(s) 145, and cold plate(s) 160 may be envisioned and fall within the scope of the appended claims. For example, in an embodiment not illustrated, the core 145 may be fixed in place as a layer between two coils 135.1, 135.2, forming a block structure, with multiple coolant plates 160 placed on two, three, or up to six sides of the resulting block. Also, while the maximum number of primary and secondary coils 135 illustrated in the figures is two of each type, more than two coils 135 of a type (low voltage and/or high voltage) may be employed if suitably electrically coupled. Additional cold plates 160 may then be employed as well as needed.

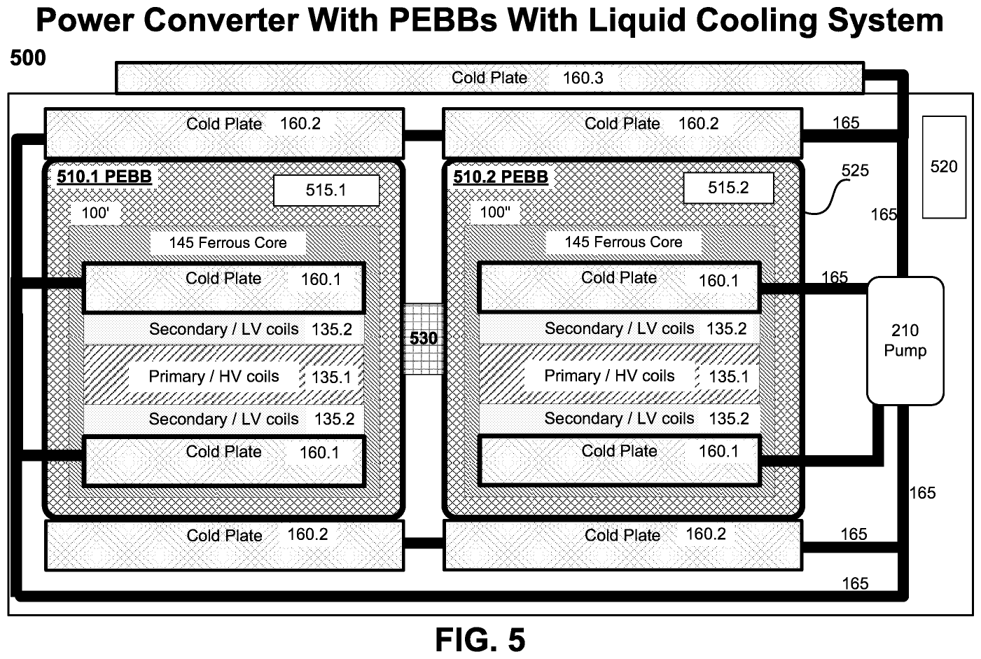

Exemplary Application, Power Converter: FIG. 5 illustrates an exemplary power converter 500 employing a liquid cooling system 200 or employing a liquid immersed transformer 700 (see FIG. 7 and associated discussion, below) according to the present system and method. The exemplary power converter 500 may include, for example and without limitation:

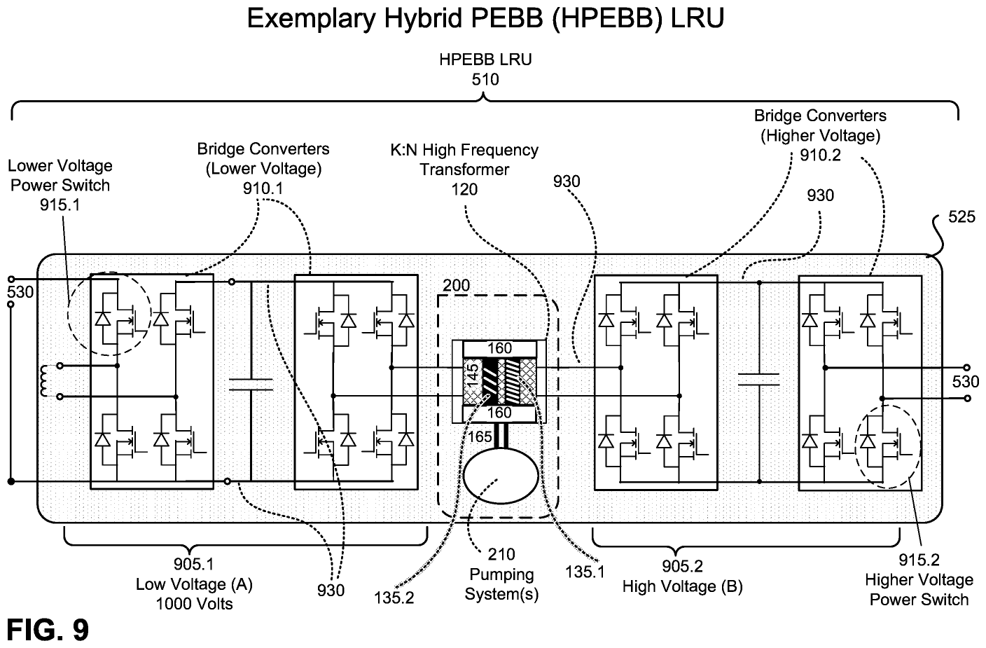

(i) Two or more power electronic building block least replacement units (PEBB) 510; each PEBB 510.1, 510.2 having its own TICP 100, and also other power elements 515 such as bridge converters with power switches (not shown in detail in FIG. 5). For further discussion of an exemplary PEBB 510, specifically a hybrid PEBB (HPEBB), see FIG. 9 below. The two PEBBs 510.1, 510.2 are electrically/current-linked by one or more power couplings 530. The power converter 500 will also have at least source (or input) power connection and at least one load (or output) power connection, not illustrated in the figure.

(ii) At least one pumping/heat-exchange sub-system 210. In the embodiment shown, a single pumping/heat-exchange sub-system 210 may provide coolant for all the cold plates of the power converter 500. In an alternative embodiment not illustrated, two or more pumping/heat-exchange sub-systems 210 may be employed.

(iii) Other converter elements 520, which may include for example and without limitation additional or supplemental cooling systems (such as a fan-based air cooling system); control systems and circuits; monitoring systems; and input and output power ports.

(iv) In addition to the cold plates 160.1 which in integral to the transformers 100, additional cold plates 160.2 may be provided for additional system cooling. Shown in FIG. 5 are four exemplary additional cold plates 160.2 which may for example be attached to the exteriors of the PEBBs 510, but other cold plates 160 may be envisioned as well. Shown in FIG. 5 is also one exemplary cold plate 160.3 attached to the exterior of the power converter 500, but additional exterior cold plates 160.3 may be employed.

It will be noted that the transformers 100 of both PEBBs 510.1, 510.2 shown in FIG. 5 employ a “C-S-P-S-C” stacking arrangement, but this is exemplary only and other stacking arrangements fall within the scope of the present system and appended claims.

Some elements of exemplary TICPs 100′, 100″ are the same or substantially similar to elements of the exemplary TICP 100.1 of FIG. 1 and/or cooling system 200 of FIG. 2, and details of those elements already described in FIG. 1 and/or FIG. 2 are not repeated here.

Coil Components (Coils) FIG. 6A provides a cross-sectional view of an embodiment of an exemplary solid coil component 135 (or simply “coil 135” in brief) of an exemplary transformer 100, which may be either a low-voltage/secondary coil 135.2 or a high-voltage primary coil 135.1. The conducting-wire/metal-film 610 may be arranged in any of a variety of flattened spiral surface arrangements on a planar interior surface of a coil support material 620, so that the wire/metal film 610 is fully embedded within the coil support material 620 except for external electrical connections 640. Consistent with the present system and method, other coiled or winding surface patterns (not illustrated) may be made as well for conducting-wire/metal-film 610 which leave the conducting filament 610 fully embedded within coil support material 620, except for external electrical connections 640. FIG. 6B provides for two cross-sectional views (I, II) of another exemplary embodiment of a solid coil component 135 (or simply “coil 135” in brief) of the exemplary transformer 100, which may be either a low-voltage/secondary coil 135.2 or a high-voltage primary coil 135.1. In the cross-sectional embodiments illustrated, electrically conducting wire 610 or metal film 610 of the coil 135 may be wound around a flattened section 620.1 of the coil support material 620; and the wire 610 and flattened section are the further embedded within an enclosing block 620.2 of coil support material 620.

In an alternative embodiment (not illustrated) the conducting-wire/metal-film 610 may be arranged in any of a variety of flattened spiral surface arrangements other flattened, winding surface patterns (suitable for magnetic induction due to current flow) on a narrow or micro-channel interior surface of coil support material 620, and still fully embedded within the coil support material 620 except for external electrical connections 640. Consistent with the present system and method, other geometric coiled or winding arrangements (not illustrated) may be made as well for conducting-wire/metal-film 610 which leave the filament fully embedded within coil support material 620, except for external electrical connections 640.

In an alternative embodiment (not illustrated), coil 135 may be constructed so that part of wire/filament 610 is embedded, wound and/or coiled, interior to coil support material 620; while a portion of wire/filament 610, possibly with suitable electrical insulation, may be proximate to or partially or wholly exposed on one or more exterior surfaces of solid coil 135.

It will be understood by persons skilled in the art that, however wire/filament 610 may be arranged or configured in relation to coil support material 610 so that: (i) coil support material 620 absorbs substantially all of the heat generated by wire/filament 610; and (ii) solid coil component 135 has at least one exposed exterior surface suitable for dissipating heat to a thermally coupled adjacent material (which may be either a cold plate 160 or another solid coil 135; or may be a surrounding heat-transfer fluid 740 such as oil 740).

Coil Materials: In an embodiment of the present system and method, the coil support material 620 may be silicon. In alternative embodiments, coil-support material(s) 620 may for include, for example and without limitation: resins, epoxies, ceramics, glass, or other non-electrically-conducting but thermally conducting substance or materials. The coils 135 may also include other materials, including for example and without limitation: (i) Polymer or polymer composites (used for insulation), for example, Epoxy or Bisphenol-A type epoxy, with 60 wt % of quartz filler added to it; and/or (ii) ceramics (e.g., alumina) used for insulation as an alternative to polymer or polymer composites.

In an embodiment, the coil support material 620 is selected to be able to readily sustain (without melting, fracture, burning, or other decay) temperatures of up to 200° C. which may be generated by the conducting (typically metallic) coils 610 embedded within. Conducting Material: In exemplary embodiments, coil 135 may be made from metals or metal alloys such as Litz wire, or other metals or metal alloys.

Exemplary HPD-HF Fluid-Immersed Transformers

In an embodiment of the present system and method, and as either an alternative to or as an addition to embodiments discussed above in this document, the entire HF transformer 120 may be structurally fixed and/or suspended within a substantially sealed container 710. The entire container may be filled with a non-electrically conducting, but heat-conducting fluid 740, such as a mineral oil (“the oil”), thereby immersing the transformer 120 in the oil 740 or other heat conducting fluid 740.

In an embodiment, a selected oil 740 is the medium of heat transfer from transformer 120. Oil 740 is both an very good thermal conductor and an excellent electrical insulator. Further, the use of a fluid 740 as the heat transfer medium, whether oil or another heat conducting fluid, ensures that the heat transfer medium has full contact with all exposed surfaces of the transformer 120, for optimal heat removal.

As compared to air as a potential cooling medium, oil 740 has higher heat capacity and better thermal conductivity. Table 1 lists approximate, relative heat capacities and thermal conductivities for water, air, and oil (selected for ranges of operating temperatures and pressures that may be applicable for the present system and method). For simplicity, air is assigned a normalized heat capacity of 1. It will be noted that: (1) relative heat capacity and thermal conductivity will vary for different kinds of oils which may be used; and (2) water has significantly better heat capacity/thermal conductivity compared with oil, but water cannot be used as the fluid 740 for direct immersion of transformers 120 due to the electrical conductivity of water; however water is suitable for use in the cooling channels 260 of cold plates 160.

TABLE 1
Relative Heat Capacities and Thermal Conductivities

| | Relative | Thermal Conductivity |
|---|---|---|
| Heat Conductor | Heat Capacity | (Watt/(Meter * Kelvin) |
| Air | 1 | ~0.02 → 0.05 |
| Oils | ~1.6 → 2.0 | ~0.1 → 0.2 |
| Water | ~4.2 | ~0.5 → 0.7 |

FIG. 7 illustrates of an exemplary HPD-HF transformer 120 which is immersed within a heat-transferring fluid (HTF) 740 (which may be oil 740), all contained within a heat management enclosure (HME) 710 with attached or integrated surface cold plates 160, according to one embodiment of the present system and method.

In FIG. 7, the combined transformer 120 proper along with the HTF 740, HME 710, and cold plates 160, hereinafter “fluid-immersed transformer” (FIT) is labeled with reference number 700.1. FIT 700.1 may for example include a high-power-density, high frequency (HPD-HF) transformer 120 which may employed for pulse-load power conversion applications.

In an embodiment, the exemplary FIT 700.1 forms a structurally integrated unit, that is, with some elements 160, 165, 710, 740 of the liquid cooling system 200 are physically and/or thermally coupled with the structure of the HPD-HF transformer 120. The FIT 700.1 is configured/assembled with two primary (high voltage/HV) coils 135.1 and two secondary (low voltage/LV) coils 135.2 in an S-P-P-S configuration.

Spatial gap for cooling fluid: In the embodiment shown in the figure, there is a spatial gap 730 between the larger planar surfaces of the two high voltage coils 135.1. This spatial gap 730 enables the heat-transferring fluid (HTF) 740 to fill the spatial gap 730, allowing for an increased rate of heat transfer between the high voltage coils 135.1 and the HTF 740. In an alternative embodiment, the gap 730 is not present, or is instead filled with a non-electrically conducting material.

Heat Management Enclosure: The transformer 120 may be attached to one or more interior surfaces 755 of the enclosure 710, or may be mechanically coupled to and suspended within the enclosure 710 via struts, brackets, or similar attachments 805 (see FIG. 8). As may be seen in FIG. 7, the transformer 120 may be placed within the enclosure 710 so that it is substantially surrounded, on multiple transformer sides and/or on multiple transformer surfaces, by the HTF 740.

The heat management enclosure (HME) 710 is sealed to prevent fluid leakage, with suitable fluid-sealed ports (not illustrated) for electrical connections to the transformer 120. On one or more exterior walls/surfaces 755 of the HME 710 are one or more cold plates 160, which are suitably bonded for effective thermal conductivity between the HME 710 and the cold plates 160. While two cold plates 160 are shown in FIG. 7, additional cold plates 160 may be placed on other exterior surfaces 755 of HME 710 as well. In an embodiment, the cold plates 160 are shaped substantially the same as a face of the enclosure wall/skin (for example, with a rectangular shape).

In an alternative embodiment, other shapes (for example, circular or oval) may be employed instead for the cold-plates 160. In an alternative embodiment, the HME 710 may have shapes other than cuboid (for example, spherical, ovoid, or with more than six exterior flat surfaces 755), with suitable shapes for the attached cold plates 160 to ensure effective thermal contact between the cold plates 160 and the HME 710.

The HME 710 may be made of a material suitable to contain high temperature fluid 740 and to convey heat from the fluid 740 to the cold plates 160. Such a material may include, for example and without limitation: a metal or metal alloy (preferably a non-ferrous metal) with suitable electrical isolation from the transformer 120; a ceramic material, a polymer material; a glass material; or a carbon-composite material.

In an alternative embodiment, the HME 710 and the cold plates may be formed, cast, or metallically-bonded to form a single, integrated structural unit. In such an embodiment, the cold plates 160 may also be viewed or understood as one or more thickened walls 755 of the heat management enclosure 710, with coolant channels 260 running through the thickened wall(s) of the HME 710.

During operation of the transformer, the heat generated from the winding coils 135.2, 135.1 and from the magnetic core body 145 will be conducted/transported to the HME skin/wall 755 via the HTF 740.

Coolant fluids/liquids: It will be noted that two different cooling fluids/liquids may be employed in conjunction with exemplary fluid-immersed transformer 700.1. For example, heat transfer fluid (HTF) 740 may be an oil or other complex hydrocarbon liquid which is effective for heat-conduction but is also an effective electrical insulator; while the liquid coolant 240 running through the cooling channels 260 of the cold plates 160 may be, for example and without limitation: tap-water, industrial-use water, chill water, de-ionized water, sea water, or water treated with suitable conditioning fluids such as antifreeze fluids, as well as possibly an oil coolant, an organic liquid coolant, or a silicone-based coolant. Other coolant liquids may be employed as well consistent with the scope of the appended claims.

In embodiments configured to employ a coolant liquid 240 which may potentially be corrosive (for example, salty sea water or ocean water used in ship-based power converters), suitable anticorrosive materials or linings may be employed for the interior surfaces of the coolant channels 260. In an alternative embodiment, filtering elements (not illustrated) may be used to filter out potentially corrosive materials.

Other details of exemplary cold plates 160 and coolant channels 260 are discussed above in this document, and the details will not be repeated here.

Pumping System: A pumping/heat-exchange sub-system 210 (“pumping system 210” in the appended claims) may be required to provide the required flow-rates, pressure and liquid quality (filtration etc.) to remove the vast majority of the waste heat generated by the transformer 120, and to reject the least amount of heat into the ambient environment. Such a pumping system may include, for example and without limitation: pumps, valves, heat exchanger, coolant conditioning components (e.g. filtration, de-gassing, de-ironing etc.), and a coolant 240 reservoir. A pumping system 210 the same or substantially similar to exemplary pumping/heat-exchange sub-system 210 of FIG. 2 may be employed here as well, and a detailed discussion is therefore not repeated.

Circulation for the heat transfer fluid: In an alternative embodiment not illustrated, it may prove advantageous for heat transfer to provide for circulation of the HTF 740 within HME 710. For this purpose, an internal fan or pumping system (not shown in FIG. 7) may be included internally within HME 710. In an alternative embodiment, a separate HTF pumping system may be situated externally to the enclosure 710, with suitable pipes to circulate HTF 740 within the interior space of HTF 740.

Additional Embodiments of a Fluid-Immersed Transformer: FIG. 8 illustrates cross-sectional views of several alternative embodiments of exemplary fluid-immersed transformers (FITs) 700, with transformers 120 which may be immersed within a heat-transferring fluid (HTF) 740, all contained within a heat management enclosure (HME) 710 with attached cold plates 160, according to alternative embodiments of the present system and method.

In FIG. 8, the FITs 740 are labeled 740.2 through 740.5, respectively. FITs 740.2-740.5 shall be generally configured and arranged in ways similar to, and with similar arrangement and configuration as exemplary FIT 740.1 of FIG. 7 above. Some details discussed above in conjunction with FIG. 7, as well as with other figures above, shall not be repeated here.

In FIG. 8, in one embodiment of the present system and method, FIT 700.2 includes one primary (high voltage/HV) coil 135.1 and one secondary (low voltage/LV) coil 135.2 with a fluid gap 730 in between in an S-G-P layout. The cooling channels 260 of the cold plate 160 are orthogonal to the plane of the cross-sectional view.

In an alternative embodiment, as illustrated by FIT 700.3, the transformer 120 has one primary (high voltage/HV) coil 135.1 and one secondary (low voltage/LV) coil 135.2 in direct physical and thermal contact with each other (P-S configuration). Struts 805 or other mechanical connections may be employed to secure the transformer 120 to the interior walls of HME 710. Heat is carried away via the HTF 740 on the sides, top, and bottom of the transformer 120. The cold plates 160 have numerous micro-channel coolant channels 260, which are orthogonal to the plane of the cross-sectional view. FIT 700.3 also illustrates exemplary transformer electrical connections 185, which are not illustrated but are necessarily present for transformers 120.

In an alternative embodiment, as illustrated by FIT 700.4, the transformer 120 has two primary (high voltage/HV) coils 135.1 and one secondary (low voltage/LV) coil 135.2, with two gaps 740 filled with HTF 740 in between the three coils 135, for a P-G-S-G-P configuration. Coolant fluid is also present in the interior space of the enclosure 710 on the input and output sides of the transformer 120. Heat is carried away via the HTF 740 on the sides, top, and bottom of the transformer 120. The cold plates 160 have numerous micro-channel coolant channels 260 which are parallel to the plane of the cross-sectional view.

In an alternative embodiment, as illustrated by FIT 700.5, the transformer 120 has two primary (high voltage/HV) coils 135.1 and one secondary (low voltage/LV) coil 135.2, all in mutual physical and thermal contact, for a P-S-P configuration. Transformer 120 is suspended within the heat management enclosure (HME) 710 via struts 805 or other mechanical connections. Heat is carried away via the HTF 740 on the sides, top, and bottom of the transformer 120.

Coolant fluid is also present in the interior space of the enclosure 710 on the input and output sides of the transformer 120. Heat is carried away via the HTF 740 on the sides, top, and bottom of the transformer 120. The cold plates 160 have numerous micro-channel coolant channels 260 which are parallel to the plane of the cross-sectional view.

Persons skilled in the relevant arts will appreciate that the embodiments of FITSs 700 of FIGS. 7 and 8 are exemplary only, and that elements of the different exemplary embodiments may be combined in various ways. Other configurations/embodiments are possible as well within the scope of the present system and method, including for example and without limitation coils 135 arranged in configurations such as S-P-S, S-G-P-S, S-P-G-S, S-G-P-G-S, S-P-P-S, S-P-G-P-S, S-G-P-G-P-S-G, and other configurations as well.

Heat transfer: In FIT 700, the transformer body 120 is immersed in a HTF 740, such as oil. Heat generated by transformer 120 is thermally transported through oil 740, to the skin/enclosure wall 755 of the HME 710. This heat is then removed by cooling liquid 240 running through the coolant channels of cold plates 160, which are in physical and thermal contact with the enclosure skin/wall 755.

Additional FIT Embodiments: In some exemplary embodiments of the present system and method for the FIT 700, the cold plates 160 (also referred to as “heat exchanger plates” 160) are configured in parallel with the plane of the coils 135, as illustrated in figures above. In alternative embodiments, the cold plates 160 may be affixed to the exterior surfaces of the enclosure walls 755 along planes which are orthogonal to the plane of the coils 135. In alternative embodiments, two or more cold plates 160 may be attached along different exterior walls of the 755 of the HME 710, so that some cold plates 160 may be attached parallel to the plane of the coils 135, and other cold plates 160 may be attached orthogonal to the plane of the coils 135. In an alternative embodiment, a single cold plate 160 attached to one wall 755 of the enclosure 710 may be sufficient to cool the transformer 120.

In an alternative embodiment, one or more cold plates 160 may be situated interior to HME 710, with suitable coolant tubes 165 attached to run coolant liquid 240 through the cold plates.

In an alternative embodiment, an oil pumping system may be employed to circulate the oil 740 in the interior of HME 710.

In an alternative embodiment, two or more transformers 120 may be contained within a single heat management enclosure 710, with cold plates 160 affixed to the single HME 710 to remove the heat generated by all the transformers.

Persons skilled in the relevant arts will also appreciated that many particulars of any final design may vary depending on application specifics, including the power to be generated by a transformer, and the spatial constraints for the intended power converter application. Thus, such details as the number of coils 135, the number and size of the core 145, the size/weight/material/placement of cold plates 160, the number and cross-section shape of coolant channels 260, types of coolant fluid(s) 240, 740 to be employed, and many other specific design factors will be determined and optimized for particular applications. Laboratory and real-world testing of proposed design choices may be necessary to identify the optimum or near-optimum, specific structural, material, and configuration choices for a particular TICP 100 or FIT 700.

It will be noted that, in addition to transformer components 135, 145 discussed in detail above, a transformer 120 may contain various additional components, such as current/electrical connectors 185, and a variety of screws, nuts, bolts, clamps, braces, and other physical components, which may either generate heat (for example, the current/electrical connectors (185)) or receive heat from the coils 135 and/or core(s) 145. Heat-transfer fluid 740 may be in physical contact and thermally conductive with exposed portions of these additional transformer elements as well, thereby removing heat from the exposed surfaces of the additional physical components.

Cooling Liquids and Fluids

In various embodiments, the present system and method employs several ongoing stages of thermal conduction and thermal convection, facilitated by direct physical contact, to transfer heat from transformer components/elements 135, 145 to either of:

(i) cold plates 160 via conduction, and further by thermal convection via the coolant liquid 240 pumped through the cold plate 160, or

(ii) convection in a heat-conducting fluid 740, to the wall(s) 755 of a heat management enclosure 710 which contains the transformer 120 and the heat-conducting fluid 740; then further via heat conduction to a cold plate 160 attached to the wall(s) 755; and still further by thermal convection via the coolant liquid 240 pumped through the cold plate 160.

In embodiments described above, the cooling liquids 240 and heat transfer fluids 740 employed have generally been characterized as liquids/fluids (such as water or water-based liquids, or most oils) which are normally in a liquid state at room temperatures; or more generally in a liquid state at temperature ranges above the freezing point of water. Such fluids may be readily stored and conveyed via tubes and pipes. For convenience, these coolants are referred to hereinafter as “room temperature coolants.”

Such room temperature coolants may have the advantages of (i) being in generous and convenient supply (for example, drawn in volume from sea water, river water, or ocean water for ship-based power converters, or even from rivers for compact land-based power converters); and/or (ii) being available in ready commercial supply (such as various oils), and/or (iii) ready and convenient storage in relatively lightweight reservoirs requiring limited or no heat insulation. Such coolants may also not require any special compressors.

In alternative embodiments, liquids/fluids 240, 740 may be employed (either in whole, or supplemental to “room-temperature” fluids) which are normally gaseous at room temperatures, and which must therefore be compressor-cooled or super-cooled to be used as liquids. Such super-cooled fluids may include for example and without limitation liquid nitrogen, liquid helium, liquid oxygen, liquid carbon dioxide, and various commercial refrigerants. Persons skilled in the art will recognize that the user of such liquids may require compressors, special storage reservoirs, and other elements not described elsewhere in this application. As such, embodiments of the present system and method with such compressor/super-cooled fluids may be heavier, and require more electricity for cooling, than embodiments employing room-temperature fluids; however, such embodiments may be useful for ultra-dense/compact power converters and for future power converters designed to generate still higher level of power (for example, with even higher voltage power-switches and higher transformer winding ratios) in very compact spaces.

Comparison with Air-Cooled Transformers

In comparison with air-cooled transformers, the present system and method (typically but not necessarily employing room-temperature coolants/fluids 240, 740) may provide certain benefits. These may include, for example and without limitation:

(i) Reduced volume (by approximately 35%), compared with air cooled HF solid state transformer;

(ii) Increased power density (˜1.5×), compared with air cooled HF solid state transformers;

(iii) Reduced heat rejection into the ambient environment (that is, reduced heating of the air, meant for activity and breathing by human personnel, of the room or facility housing a power converter), which additionally helps decrease the demands on air-conditioning/cooling for the human environment; and

(iv) Both the transformer with integrated cold plates (TICP) 100 and the fluid immersed transformer (FIT) 700 will be better-suited (as compared to air-cooled transformers) to fit into tight/constrained spaces on board military and commercial ships, with the reduced space providing beneficial usage for the “saved space” for other purposes.

Exemplary Application: HPEBB

FIG. 9 illustrates an exemplary power electronics building block (PEBB) 510 employing a liquid/fluid cooling system 200, 700 (see FIGS. 2, 5 and 7 and associated discussion, above) according to the present system and method. More specifically, FIG. 9 illustrates an exemplary hybrid power electronics building block (HPEBB) 510.1. Note that PEBBs may also be referred to as “[hybrid] power electronic building block least replacement units” (PEBB LRU or HPEBB LRU”) 510/510.1.

A legacy PEBB 510 typically employs power switches 915 of equal voltage ratings (for example, 1700 volts for 1000 volt nominal operation) throughout the PEBB 510. A legacy PEBB also typically employs a high power transformer 120 with a 1-to-1 winding ratio.

Exemplary HPEBB LRU 510.1 employs both lower-voltage and higher-voltage switches 915 (hence the term “hybrid”), which may in some embodiments be Silicon Carbide (SiC) switches. For example, in an exemplary embodiment the lower voltage switches 915.1 may be 1700 volt-rated switches for 1000 volt nominal operation, while the high voltage switches 915.2 may be 10000 volt-rated switches for 6000 volt nominal operation. In general, the operational voltages may be A and B, where B>A, and where A may be for example and without limitation 1000 volts or 2000 volts, or other voltages; and B may be for example and without limitation 2000 volts, 3000 volts, 6000 volts, or other voltages. The present systems and methods for liquid cooling are designed, in part, for cooling for HPEBB LRUs 510 and power converters 500 which benefit from the higher power switches 115.2 which are in development (or just emerging) at the time of the present application.

Exemplary HPEBB LRU 510 also employs a high-power, high-frequency transformer 120 with a K:N winding ratio (N>K; K=1, 2, . . . ; N=2, 3, . . . ).

In various embodiments, an HPEBB based converter 500 according to the present system and method may require fewer HPEBB LRUs 510 than the number of legacy PEBB LRUs which would be required in a legacy system (legacy PEBBs may be referred to as “PEBB 1000 LRUs”, and typically employ only power switches rated for 1000 volt nominal operation). Power converters 500 according to the present system and method may thereby reducing the total volume and weight of the power converter 500, and increasing the power density and specific power of the converter 500. In one embodiment of the present system and method, a power switch 915 is implemented as a MOSFET (metal-oxide semiconductor field effect transistor) in parallel with a diode, as illustrated in FIG. 9. In an alternative embodiment, a power switch 915 is implemented as in IGBT (insulated gate bipolar transistor) in parallel with a diode, as illustrated in FIG. 9. Persons skilled in the relevant arts will appreciate that a power switch 915 may be implemented as other combinations of one or more power transistors and other components, such as GaN (Gallium Nitride) wide band gap devices, JFET, IGCT (integrated gate-commutated thyristor), and diodes, within the scope of the present system and method.

In the exemplary HPEBB LRU of 510 of FIG. 9, a total of four bridge converters 910 are employed. In alternative embodiments, a total of two, three, or more than four bridge converters 910 may be used. It will also be understood that in the art, the bridge converters 910 are sometimes referred to by other terminologies, including for example and without limitation: power stage, power bridge, H-bridge converters, and full bridge converters.

The exemplary HPEBB LRU 510 also illustrates a K:N (N=2, 3, . . . ) high frequency (HF) transformer 120 configured to link the lower voltage elements 905.1 and the high voltage elements 905.2. That is, exemplary HPEBB 510 couples the lower voltage elements 905.1 and the higher voltage elements 905.2 via a high frequency (HF) transformer 120 with a higher than unity (1:1) winding ratio such as K:N, such as for example and without limitation, a 1:3 ratio or a 1:6 ratio.

In some embodiments of the present system, an exemplary high power switching device 915.2 may consist of or may include 10 kV SiC MOSFETs which at the time of this application are under development by Cree (Cree, Inc., 4600 Silicon Drive, Durham, N.C., 27703). In exemplary embodiments, the bridge converters 910.1 on the low voltage side 905.1 may use 1.7 kV SiC MOSFET/IGBT devices, while the bridge converters 910.2 on the high voltage side 905.2 may use 10 kV SiC MOSFET/IGBT devices. In an exemplary embodiment with the HF solid state transformer 120 having a winding/turn ratio of 1:3 (one (1) on the low voltage side, and three (3) on the high voltage side), in which case multiple such HPEBBs 510 can be configured in a single power converter for a space and power-density efficient 1 kVdc-to-13.8k V AC power conversion.

In alternative embodiments, high power switches 115.2 may be implemented via other high power switches known or in development, including but not limited to high power MOSFETs and/or high power IGBTs. The higher turn ratio (for example 1:3) of the HF transformer 120 provides a voltage boost, and makes the hybrid PEBB (1000/6000) no longer voltage limited for higher medium voltage (MV) (>12 kV) applications.

HPEBB heat management: The K:N high power density, high frequency transformer 120, which provides for galvanic isolation between the low voltage components 905.1 and the high voltage components 905.2, may generate a level of heat (and a rate of heat production) sufficient to benefit from the exemplary cooling systems 100, 200, 700 described throughout this document. Consequently, HPEBB LRU 510 may include cooling elements described throughout this document, including for example and without limitation: cooling fluids/liquids 240, 740.

Power converter volume and weight: The hybrid PEBB LRU converter 510 volume and weight may increase somewhat due to the use of PEBB 6000 components 910.2, 915.2 on the primary or high voltage side 905.2; and may further increase due to additional cooling requirements. However, due to the reduced requirement for the total number of HPEBB LRUs 510 (as compared with legacy power converters), in various embodiments the total volume and weight of an exemplary 1 kVdc-13.8 kV 1 MW hybrid PEBB power converter 510 will be significantly reduced (as compared with the weight/volume of a legacy PEBB 1000 LRU-based power converter with the same voltage/power capacity).

Correspondingly, in various embodiments the present system provides for an HPEBB power converter 500.1 with a power density and specific power which is significantly increased via the use of HPEBB LRUs 510 which employ the cooling systems and methods of the present application (as compared with the power density/specific power of a legacy PEBB 1000 LRU-based power converter with the same total power capacity).

The exemplary HPEBB power converter 500 is typically contained in a cabinet or housing 525 (see FIG. 5 above) which contains all the above elements, as well as others not shown in the figure but known in the art. The cabinet 525 may include, contain or have attached, for example and without limitation: various internal structural support elements (not shown), system buses, power buses, ports for connection with exterior elements and connection to exterior systems, vents for airflow, pipes or ducts for coolants associated with cooling system(s) 525, exterior status display(s), electronics for feedback and control systems (including processors and memory), and other elements not shown in FIG. 2.

The cabinet or housing 525 may include the elements of one or more cooling systems 210, as discussed in detail in this document.

Control Systems

In various exemplary embodiments, the present system and method may entail the use of or integration of control systems for regulation of switches, capacitors, cooling systems, valves, pumps, filters, and other factors requiring real-time control. Such control systems may entail the use of microprocessors, digital input/output elements, memory (such a random access memory (RAM) and various forms of non-volatile memory), display systems, audio input and/or audio signalling systems, and/or analogue control elements known in the art or to be developed. Such control systems may employ suitable-coded software, stored in memory, to control various aspects of system operations.

Where computer code is required for the present system and method, such as for control systems running on microprocessors, computer readable code can be disposed in any known computer usable medium including semiconductor, magnetic disk, optical disk (such as CD-ROM, DVD-ROM) and as a computer data signal embodied in a computer usable (e.g., readable) transmission medium (such as a carrier wave or any other medium including digital, optical, or analog-based medium). As such, the code can be transmitted over communication networks including the Internet and intranets.

It is understood that control functions or monitoring functions to be accomplished in conjunction with the systems and techniques described above can be represented in a core (such as a CPU core) that is embodied in program code and can be transformed to hardware via suitable circuits, wireless communications, and/or optical messaging.

### VII. CONCLUSION

For maritime purposes, including Naval applications such as Naval Power System and Energy System (NPES) technologies, HPEBB bridge converters 910, HPEBB LRUs 510, and power converters 500 are being developed as part of a multi-function energy storage module (MFESM) effort. Emerging hybrid PEBB LRUs 510 in particular employ high-power transformers which can generate large amounts of heat in compact spaces. The liquid/fluid cooling systems 200 for HPD-HF transformers of the present system and method offer significant advantages in managing the heat generated by such systems.

Alternative embodiments, examples, and modifications which would still be encompassed by the disclosure may be made by those skilled in the art, particularly in light of the foregoing teachings. Further, it should be understood that the terminology used to describe the disclosure is intended to be in the nature of words of description rather than of limitation.

Those skilled in the art will also appreciate that various adaptations and modifications of the preferred and alternative embodiments described above can be configured without departing from the scope of the disclosure. Therefore, it is to be understood that, within the scope of the appended claims, the disclosure may be practiced other than as specifically described herein.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

It should be noted that the simulation, synthesis, and/or manufacture of the various embodiments of this invention can be accomplished, in part, through the use of a variety of materials, including metals, non-metals, resins, epoxies, semi-conductors; glass, polymers, ferrous materials, non-ferrous materials, conductors, insulators; and water or water-based liquids for cooling, oils and other hydrocarbon-based fluids for cooling, some known in the art and some yet to be developed.

It is to be appreciated that the Detailed Description section (and not the Summary and Abstract sections) is primarily intended to be used to interpret the claims. The Summary and Abstract sections may set forth one or more but not all exemplary embodiments of the present invention as contemplated by the inventor(s), and thus, are not intended to limit the present invention and the appended claims in any way.

Further regarding the appended claims, any and all reference signs/numbers are provided to make the claims easier to understand, and are not to be treated as limiting the extent of the matter protected by the claims; their sole function is to provide for clear reference to elements in the disclosure and drawings.

What is claimed is:

1. A liquid cooled transformer (100) comprising:
a plurality of coil components (135) each for conducting an electric current;
a core (145) configured to convey a magnetic flux between the plurality of coil components (135);
a cold plate (160) in surface contact with and thermally coupled with at least one of the core (145) and a coil component (135.1, 135.2) of the plurality of coil components (135);
wherein the cold plate (160) comprises a coolant channel (260) configured to convey a liquid coolant (240) within the cold plate (160).

2. The liquid cooled transformer (100) of claim 1, wherein the cold plate (160) comprises a non-ferrous metal.

3. The liquid cooled transformer (100) of claim 1, wherein the cold plate (160) comprises two or more coolant ports (175) for inflow and outflow of the liquid coolant (240).

4. The liquid cooled transformer (100) of claim 1, wherein the coil component (135) comprises:
a continuous electrically conducting material (610) which is wound, coiled, or surfaced patterned to generate a magnetic flux when an electric current runs through the conducting material (610); and
a heat-conducting, non-electrically-conducting, non-ferrous coil support material (620) configured to substantially contain or embed the electrically conducting material (610) and to conduct heat away from the electrically conducting material (610).

5. The liquid cooled transformer (100) of claim 1, wherein:
a first surface of the cold plate (160) and a second surface of the at least one of the core (145) and the coil component (135.1, 135.2) with which the cold plate is thermally coupled are so mutually shaped as to facilitate extended surface contact and thereby the effective transfer of heat between the second surface at least one of the core (145) and the coil component (135.1, 135.2) and the first surface of the cold plate (160).

6. The liquid cooled transformer (160) of claim 5, wherein the first surface and the second surface are flat surfaces.

7. The liquid cooled transformer (100) of claim 1, wherein:
a single cold plate (160) has a first surface and a second opposing surface, each surface in contact with a different one of the transformer elements from among the core (145) and the two coil components (135.1, 135.2).

8. The liquid cooled transformer (100) of claim 1, wherein:
the cold plate (160) is physically situated between, in physical contact with, and thermally coupled with at least one of:
both the core (145) and one of the coil components (135.1, 135.2); and
both of the coil components (135.1, 135.2).

9. The liquid cooled transformer (100) of claim 1, further comprising at least two separate cold plates (160), where the at least two cold plates (160) are configured and arranged to be in physical contact with and in thermal contact with at least two different non-adjoining transformer elements from among the core (145), the first coil component (135.1), and the second coil component (135.2).

10. The liquid cooled transformer (100) of claim 1, further comprising at least two separate cold plates (160), where the at least two cold plates (160) are configured and arranged to be in physical contact with and in thermal contact with at least three different transformer elements from among the core (145), the first coil component (135.1), and the second coil component (135.2).

11. A fluid-immersed transformer (FIT) (700) comprising:
a plurality of transformer components (135, 145) comprising (i) a plurality of coil components (135) each for conducting an electric current, and (ii) a core (145) configured to convey a magnetic flux between the plurality of coil components (135);
a heat management enclosure (710) containing the transformer components (135, 145), and configured to contain a heat conducting fluid (740), the heat conducting fluid (740) suitable for transferring heat from the plurality of coil components (135) and the core (145) to an exterior wall (755) of the heat management enclosure (710); and
a cold plate (160) which is in surface contact with and thermally coupled with an exterior wall (755) of the heat management enclosure (710), or which is integrated into the exterior wall (755) of the heat management enclosure (710), wherein:
the cold plate (160) comprises a coolant channel (260) configured to convey a liquid coolant (240) within and through the cold plate (160); and
heat conveyed from the transformer components (135, 145) to the exterior wall (755) is further eliminated via transfer into the liquid coolant (240) flowing through the cold plate.

12. The FIT (700) of claim 11, wherein the cold plate (160) comprises a non-ferrous metal.

13. The FIT (700) of claim 11, wherein the cold plate (160) comprises two or more coolant ports (175) for inflow and outflow of the liquid coolant (240).

14. The FIT (700) of claim 11, wherein the coil component (135) comprises:
a continuous electrically conducting material (610) which is wound, coiled, or surfaced patterned to generate a magnetic flux when an electric current runs through the conducting material (610); and
a heat-conducting, non-electrically-conducting, non-ferrous coil support material (620) configured to substantially contain or embed the electrically conducting material (610) and to conduct heat away from the electrically conducting material (610).

15. The FIT (700) of claim 11, wherein the heat conducting fluid (740) is a non-electrically conducting oil.

16. The FIT (700) of claim 11, wherein the liquid coolant (240) is a water-based fluid.

17. The FIT (700) of claim 11, wherein the plurality of transformer components (135, 145) are configured with a spatial gap (730) between at least two of the components (135, 145), wherein the heat conducting fluid (740) fills the spatial gap (730) for increased thermal convection.

18. The FIT (700) of claim 11, comprising at least three coils (135).

19. The FIT (700) of claim 11, wherein at least one of the core (145) and one of the coils (135) is in direct physical and thermal contact with an interior surface of the heat management enclosure (710).

20. The FIT (700) of claim 11, wherein:
all of the coils (135) and core(s) (145) are suspended within the heat management enclosure (710) via struts (805); and
the coils (135) and core(s) (145) are all in direct physical and thermal contact, and are substantially surrounded on all sides by the heat conducting fluid (740).

21. The FIT (700) of claim 11, wherein:
all of the coils (135) and core(s) (145) are suspended within the heat management enclosure (710) via struts (805); and
a spatial gap (730) is present between at least two of the components (135, 145);
the heat conducting fluid (740) substantially surrounds all of the coils (135) and core(s) 145, and the heat conducting fluid (740) further fills the spatial gap (730) for increased convection.

22. The FIT (700) of claim 11, further comprising a pump configured to circulate the heat conducting fluid (740).

23. A cooling system (500) for a high-power transformer system (100, 700) which comprises a transformer (120), the cooling system (500) comprising:
a pumping system (210) configured to pump a coolant liquid (240); and
a cold plate (160) in physical contact with and thermally conductive with one or more elements (135, 145, 710) of the high-power transformer system, the cold plate (160) having an interior coolant channel (260) configured to enable the coolant liquid (240) to pass through the interior of the cold plate (160), wherein:
the cold plate (160) is configured to remove heat generated by the transformer (120) of the high-power transformer system (100) via the coolant liquid (240) received by the cold plate from the pumping system (210).

24. The cooling system (500) of claim 23, wherein the cold plate (160) is in physical contact with and thermally conductive with at least one of a coil (135) of the transformer (120) and a ferrous core (145) of the transformer (120).

25. The cooling system (500) of claim 23, further comprising a plurality of cold plates, wherein each respective cold plate (160) of the plurality is in physical contact with and thermally conductive with at least one of a respective primary coil (135.1) of the transformer (120), one of a respective secondary coil (135.2) of the transformer (120), or one of a respective ferrous core (145) of the transformer (120).

26. The cooling system (500) of claim 23, wherein the cold plate (160) is situated between, in physical contact with, and thermally conductive with at least two of a primary coil (135.1) of the transformer (120), a secondary coil (135.2) of the transformer (120), and a ferrous core (145) of the transformer (120).

27. The cooling system (500) of claim 23, wherein the coolant liquid (240) comprises at least one of water, distilled water, tap-water, industrial-use water, chilled water, de-ionized water, salt water, sea water, and water treated with antifreeze fluids.

28. The cooling system (500) of claim 23, wherein the coolant liquid (240) comprises at least one of an oil coolant, a hydrocarbon-based coolant, an organic liquid coolant, and a silicone-based coolant.

29. The cooling system (500) of claim 23, further comprising a heat management enclosure (710) which contains and surrounds the transformer (120), wherein:
the heat management enclosure (710) is further configured to contain a heat-transfer fluid (740);
the heat management enclosure (710) is thermally conductive; and
the cold plate (160) is in physical contact and thermally coupled with the heat management enclosure (710);
wherein:
the cooling system (500) is configured and arranged so that heat generated by the transformer (120) is thermally transferred in succession to the heat-transfer fluid (740), to the heat management enclosure (710), to the cold plate (160), to the coolant liquid (240).

30. The cooling system (500) of claim 23, wherein the heat-transfer fluid (740) is an oil.

31. The cooling system (500) of claim 23, wherein:
the transformer (120) is configured with a spatial gap (730) between at least two of (i) a pair of coils (135) of the transformer (120) and (ii) a coil (135) of the transformer and a core (145) of the transformer (120), and
the cooling system (500) further comprises the spatial gap (730), where the heat-transfer fluid (740) is configured to fill and provide heat transfer within the spatial gap (730).

32. The cooling system (500) of claim 23, wherein:
the transformer (120) is suspended inside a heat management enclosure (710) so that the heat-transfer fluid (740) is in physical and thermal contact with substantially all exposed surfaces of the transformer (120).

33. A power electronics building block (PEBB) 510 for a power converter 500, the PEBB (510) comprising:
a first bridge converter (915.1) for low voltages;
a second bridge converter (915.2) for high voltages;
a transformer (120) which electrically couples the first bridge converter (915.1) and the second bridge converter (915.2);
a pumping system (210) configured to pump a coolant liquid (240); and
a cold plate (160) which is thermally coupled with the transformer (120), the cold plate (160) comprising a coolant channel (260) for conveying the coolant liquid (240) through the cold plate (160), wherein:
heat generated by the transformer (120) is thermally conducted to an environmental heat sink (295) via thermal conduction from the transformer (120) to the cold plate (160) and via thermal convection by the coolant liquid (240) to the environmental heat sink (295).

34. The PEBB 510 of claim 33, wherein the coolant liquid (240) is a water-based liquid.

35. The PEBB 510 of claim 33, wherein the cold plate (160) is in direct physical contact with one or more heat-generating elements (135, 145) of the transformer (120).

36. The PEBB 510 of claim 33, further comprising:
a heat management enclosure (710) which contains and surrounds the transformer (120), wherein:
the heat management enclosure (710) is further configured to contain a heat-transfer fluid (740);
the heat management enclosure (710) is thermally conductive; and
the cold plate (160) is in physical contact and thermally coupled with the heat management enclosure (710);
wherein:
the cooling system (500) is configured and arranged so that heat generated by the transformer (120) is thermally transferred in succession to the heat-transfer fluid (740), to the heat management enclosure (710), to the cold plate (160), and to the coolant liquid (240).

37. The PEBB 510 of claim 36, wherein the heat-transfer fluid (740) is an oil.

38. The PEBB 510 of claim 36, wherein the transformer (120) is a high-power density, high frequency transformer.

39. The PEBB 510 of claim 38, wherein:
the transformer (120) employs a K:N winding ratio, wherein N>K; and
a heat generated by the transformer (120) with the K:N winding ratio is higher than a heat generated by a transformer with a 1:1 winding ratio.
